(19) United States
(12) Patent Application Publication
(10) Pub. No.: US 2026/0237608 A1
(43) Pub. Date: Aug. 13, 2026

(54) SUBSTRATE PROCESSING APPARATUS INCLUDING SURFACE-TREATED COMPONENT AND METHOD OF PERFORMING SURFACE TREATMENT ON THE COMPONENT OF THE SUBSTRATE PROCESSING APPARATUS

(71) Applicant: SAMSUNG ELECTRONICS CO., LTD., Suwon-si (KR)

(72) Inventors: Jeonghoon Nam, Suwon-si (KR); Bonseung Goo, Suwon-si (KR); Youngkwon Kim, Suwon-si (KR); Younseon Wang, Suwon-si (KR); Changsup Kwon, Anseong-si (KR); Mingyo Byeon, Suwon-si (KR); Youngyeon Ji, Anseong-si (KR)

(73) Assignees: SAMSUNG ELECTRONICS CO., LTD., Suwon-si (KR); Hansol Iones Co., Ltd., Gyeonggi-do (KR)

(21) Appl. No.: 19/276,837

(22) Filed: Jul. 22, 2025

(30) Foreign Application Priority Data
Feb. 13, 2025 (KR) 10-2025-0018790

(51) Int. Cl. H01J 37/32; H01L 21/687

(52) U.S. Cl. CPC H01J 37/32495; H10P 72/7616; H01J 2237/3321

(57) ABSTRACT

Provided is a component used in a semiconductor process. The component includes a base material including at least one of a metal and a ceramic, a first coating layer on the base material and configured to suppress halogen radicals from physically permeating the base material, and a second coating layer on the first coating layer, wherein the first coating layer includes particles having a size sufficient to suppress the halogen radicals from permeating the base material.

### CROSS-REFERENCE TO RELATED APPLICATION

This application is based on and claims priority under 35 U.S.C. § 119 to Korean Patent Application No. 10-2025-0018790, filed on Feb. 13, 2025, in the Korean Intellectual Property Office, the disclosure of which is incorporated by reference herein in its entirety.

### BACKGROUND

The present disclosure relates to a substrate processing apparatus including a surface-treated component and a method of performing surface treatment on a component of the substrate processing apparatus, and more particularly, to a substrate processing apparatus which includes a surface-treated component and in which a plasma process is performed and a method of performing surface treatment on a component of the substrate processing apparatus.

Recently, in the semiconductor manufacturing industry, there is a steady trend of decreasing minimum line-widths in semiconductor integrated circuit processes to increase the operating speed and the information storage capacity per unit area of semiconductor chips. In addition, the sizes of semiconductor devices, such as transistors, which are integrated on semiconductor substrates, have been gradually reduced.

Such semiconductor devices may be fabricated through deposition processes, photolithography processes, etching processes, diffusion processes, and the like. In particular, deposition processes are essential processes required to be improved for reproducibility and reliability in semiconductor device fabrication. For example, deposition films are formed on substrates by methods such as sol-gel methods, sputtering, electro-plating, evaporation, chemical vapor deposition, physical vapor deposition, molecular beam epitaxy, and atomic layer deposition. Particularly, when deposition films are formed on substrates, because chemical vapor deposition and atomic layer deposition have better characteristics in terms of deposition characteristics and uniformity of the deposition films than other deposition methods, chemical vapor deposition and atomic layer deposition are most commonly used.

### SUMMARY

The present disclosure provides a substrate processing apparatus including a component on which a surface treatment has been performed to improve reliability and a method of performing surface treatment on a component of the substrate processing apparatus.

In addition, the present disclosure is not limited to the above aspect, and the above and other aspects of the present disclosure will be clearly understood by those of ordinary skill in the art from the following description.

According to an aspect of the present disclosure, there is provided a component used in a semiconductor process, the component including a base material that includes at least one of a metal and a ceramic, a first coating layer on the base material and configured to suppress halogen radicals from physically permeating the base material, and a second coating layer on the first coating layer, wherein the first coating layer includes particles having a size sufficient to suppress the halogen radicals from permeating the base material.

According to another aspect of the present disclosure, there is provided a component used in a semiconductor process, the component including a base material that includes at least one of a metal and ceramic, a first coating layer on the base material, and a second coating layer on the first coating layer and configured to protect the first coating layer, wherein a vapor pressure of a compound of both a metal constituting the second coating layer and a halogen is less than a vapor pressure of a compound of both a metal constituting at least one of the base material and the first coating layer and the halogen.

According to another aspect of the present disclosure, there is provided a semiconductor process chamber used in a semiconductor process, the semiconductor process chamber including a component that includes at least one of a metal and a ceramic, wherein the component includes a base material including at least one of a metal and a ceramic, a first coating layer on the base material and configured to suppress halogen radicals from physically permeating the base material, and a second coating layer on the first coating layer and configured to protect the first coating layer, the first coating layer includes particles having a size sufficient to suppress the halogen radicals from permeating the base material, and a vapor pressure of a compound of both a metal constituting the second coating layer and a halogen is less than a vapor pressure of a compound of both a metal constituting at least one of the base material and the first coating layer and the halogen.

According to another aspect of the present disclosure, there is provided a method of performing surface treatment on a component used in a semiconductor process, the method including preparing a base material including at least one of a metal and a ceramic, forming a first coating layer on the base material, and forming a second coating layer on the first coating layer, wherein the forming of the first coating layer is performed such that halogen radicals are suppressed from physically permeating the base material, and the forming of the second coating layer is performed such that a vapor pressure of a compound of both a metal constituting the second coating layer and a halogen is less than a vapor pressure of a compound of both a metal constituting at least one of the base material and the first coating layer and the halogen.

The forming of the first coating layer may be performed such that particles constituting the first coating layer have a size of about 5 nm or less (the term “about”means ±5% for purposes of this specification).

At least one of the forming of the first coating layer and the forming of the second coating layer may be performed by an atomic layer deposition method.

The atomic layer deposition method may include at least one reactant from among CH₃COOH, HCOOH, H₂O, O₃, O₂, and O, when the atomic layer deposition method is performed.

The atomic layer deposition method may be performed at a temperature of about 50° C. to about 500° C.

The forming of the first coating layer may be performed such that the first coating layer suppresses halogen radicals from reacting with the base material at a temperature of up to about 650° C.

The forming of the second coating layer may be performed such that the second coating layer suppresses halogen radicals from reacting with the base material at a temperature of up to about 650° C.

The forming of the second coating layer may be performed such that a vapor pressure of a compound of both the metal of the second coating layer and fluorine is less than a vapor pressure of aluminum fluoride.

### BRIEF DESCRIPTION OF DRAWINGS

Embodiments will be more clearly understood from the following detailed description taken in conjunction with the accompanying drawings in which:

FIG. 1 is a diagram illustrating a substrate processing apparatus according to an embodiment;

FIG. 2 is a cross-sectional view illustrating a component used in a semiconductor process, according to an embodiment;

FIG. 3 is a transmission electron microscopy (TEM) image showing a first coating layer according to an embodiment;

FIG. 4 is a TEM image showing a second coating layer according to an embodiment;

FIG. 5 is a TEM image showing a component after a cleaning process in Comparative Example 1;

FIG. 6 is an energy dispersive spectroscopy (EDS) mapping data image showing the component after the cleaning process in Comparative Example 1;

FIG. 7 is a TEM image showing a component after a cleaning process in Comparative Example 2;

FIG. 8 is an EDS mapping data image showing the component after the cleaning process in Comparative Example 2;

FIG. 9 is a TEM image showing a component after a cleaning process in an Example;

FIG. 10 is an EDS mapping data image showing the component after the cleaning process in the Example; and

FIG. 11 is a flowchart illustrating a method of forming a plurality of coating layers on a substrate, according to an embodiment.

### DETAILED DESCRIPTION OF EMBODIMENTS

Hereinafter, embodiments of the present disclosure will be described in detail with reference to the accompanying drawings. Like components are denoted by like reference numerals throughout the specification, and repeated descriptions thereof are omitted. In the drawings, the thickness or size of each layer may be exaggerated for convenience and clarity of descriptions, and thus, the shape and proportion of each layer may be somewhat different from the actual shape and actual proportion thereof.

Herein, terms indicating spatial positions, for example, “upper side”, “lower side”, “on”, “over”, “under”, and the like, are used to describe relative position relations between elements shown in the drawings, and it will be understood that such terms are used only for better understanding and are not to be construed in any way as limiting the present disclosure. Terms regarding spatially relative positions are intended to encompass changes according to directions of semiconductor devices in addition to directions illustrated in the drawings. That is, semiconductor devices may be oriented in various directions when used (or fabricated), and even in such cases, position-related terms used herein will be easily understood by those of ordinary skill in the art. Also, for purposes of this specification, a statement like “at least one of A and B” has the same meaning as “A, B, or A and B.”

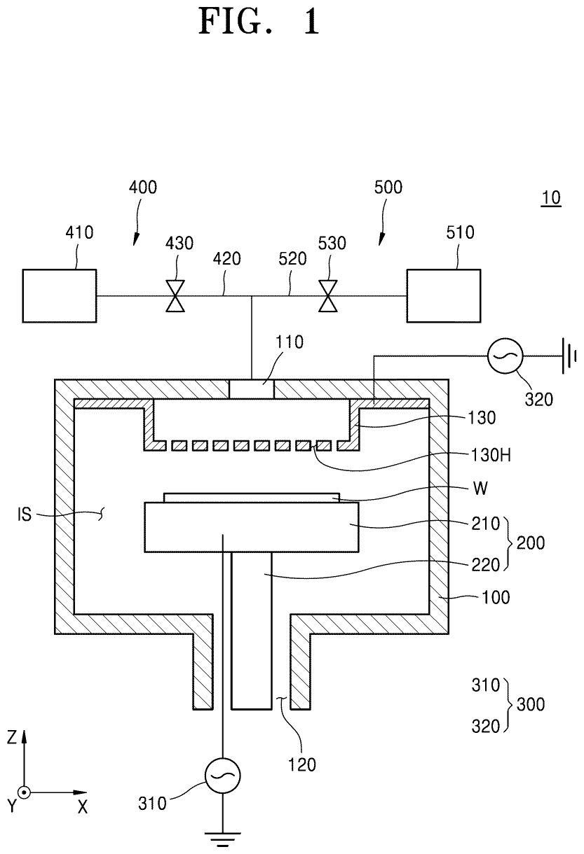

FIG. 1 is a diagram illustrating a substrate processing apparatus according to an embodiment.

Referring to FIG. 1, a substrate processing apparatus 10 may include a process chamber 100, a substrate supporting device 200, a power supply 300, a reaction gas supply device 400, and a cleaning gas supply device 500. In an embodiment, the substrate processing apparatus 10 may be configured to perform a semiconductor process on a substrate W. The substrate processing apparatus 10 may perform plasma processing on the substrate W. The substrate processing apparatus 10 may perform a deposition process for forming a thin film on the substrate W and a cleaning process for removing reaction by-products generated in the deposition process.

Although FIG. 1 illustrates an example in which the substrate processing apparatus 10 includes a plasma-enhanced chemical vapor deposition (PECVD) apparatus, the substrate processing apparatus 10 may include various apparatuses. For example, the substrate processing apparatus 10 may include a deposition apparatus, such as a CVD apparatus or a sputtering apparatus, and an etching apparatus, such as a plasma etching apparatus.

The process chamber 100 includes an internal space IS in which a semiconductor process is performed, and a gas inlet port 110 for introducing a gas to the internal space IS may be arranged at one side (for example, the upper end) of the process chamber 100. In addition, an exhaust port 120 for exhausting reaction by-products and residual gases generated in a semiconductor process may be arranged at one side (for example, the lower end) of the process chamber 100. Although not shown in FIG. 1, the exhaust port 120 may be connected to an exhaust line. A material in the internal space IS may be discharged through the exhaust line, and thus, the internal space IS of the process chamber 100 may be maintained at lower pressure than atmospheric pressure.

A shower head 130 may eject a process gas supplied to the process chamber 100. The shower head 130 may include ejection holes 130H for ejecting the process gas, and the process gas may be uniformly ejected onto the substrate W by the ejection holes 130H. The shower head 130 may be arranged in an upper portion of the internal space IS of the process chamber 100 to face the substrate supporting device 200. The shower head 130 may have a diameter that is larger than the diameter of the substrate supporting device 200. The shower head 130 may include a metal. For example, the shower head 130 may include aluminum (Al), nickel (Ni), and/or stainless steel (SUS).

Although not shown in FIG. 1, the process chamber 100 may include a substrate inlet port in one sidewall thereof. The substrate inlet port may provide a passage through which the substrate W may enter and exit from the inside of the process chamber 100. The substrate inlet port may be opened and closed by an opening-closing member, such as a door.

The substrate supporting device 200 may be arranged inside the process chamber 100 and may be configured to support the substrate W. The substrate supporting device 200 may be arranged in a lower portion of the internal space IS. In an embodiment, the substrate supporting device 200 may be configured to support the substrate W by using electrostatic force. In an embodiment, the substrate supporting device 200 may be configured to support the substrate W by vacuum-sucking the substrate W. The substrate supporting device 200 may include a body 210, on which the substrate W is loaded, and a support 220 that supports the body 210.

The body 210 may include a loading surface on which the substrate W is loaded. The body 210 may be configured to support the substrate W placed on the loading surface. The upper surface of the body 210 may mostly have a circular shape and may have a diameter that is larger than that of the substrate W. The support 220 may be arranged under the body 210 and may move the body 210 up and down. In an embodiment, the body 210 may include a heater for heating the substrate W.

For example, the body 210 and/or the support 220 may include a ceramic and/or a metal. For example, the ceramic may include aluminum oxide, aluminum nitride, yttrium oxide, silicon carbide, silicon, silicon nitride, and/or zinc oxide. For example, the metal may include aluminum (Al), yttrium (Y), titanium (Ti), nickel (Ni), stainless steel (SUS), tungsten (W), and/or copper (Cu).

Here, the “substrate W” may refer to the substrate W itself or to a stack structure including the substrate W and a certain layer or film or the like formed on a surface of the substrate W. In addition, the “surface of the substrate W” may refer to an exposed surface of the substrate W itself or to an exposed surface of a certain layer or film or the like formed on the substrate W. For example, the substrate W may include a wafer or may include a wafer and at least one material film on the wafer. The material film may include an insulating film, a polymeric film, or the like formed on the wafer.

The power supply 300 may apply radio-frequency (RF) power to the inside of the process chamber 100. In an embodiment, the power supply 300 may include an RF power supply for exciting a reaction gas in the internal space IS to a plasma state. The power supply 300 may include a first power supply 310 and a second power supply 320. The first power supply 310 may be electrically connected to the substrate supporting device 200, and the second power supply 320 may be electrically connected to the shower head 130. The first power supply 310 may be electrically connected to the body 210 of the substrate supporting device 200.

Although FIG. 1 illustrates an example in which the substrate processing apparatus 10 includes a capacitively coupled plasma source, the present disclosure is not limited thereto. For example, the substrate processing apparatus 10 may include an inductively coupled plasma source.

The reaction gas supply device 400 may supply a reaction gas to the internal space IS through the gas inlet port 110. The reaction gas supply device 400 may include a first gas storage unit 410, a first gas supply line 420, and a first valve 430. The first gas storage unit 410 may store the reaction gas that is to be supplied to the internal space IS. The first gas supply line 420 may supply the reaction gas stored in the first gas storage unit 410 to the inside of the process chamber 100 by connecting the first gas storage unit 410 and the gas inlet port 110 to each other. The first valve 430 may be mounted on the first gas supply line 420 and may open and close the first gas supply line 420 or may adjust the flow rate of the reaction gas supplied to the internal space IS. The reaction gas may be determined according to a material to be deposited on the substrate W. For example, the reaction gas may include SiH₄, TEOS, N₂O, NH₃, N₂, CH₄, CF₄ and/or C₂F₆.

The cleaning gas supply device 500 may supply a cleaning gas to the internal space IS through the gas inlet port 110. The cleaning gas supply device 500 may include a second gas storage unit 510, a second gas supply line 520, and a second valve 530. The second gas storage unit 510 may store the cleaning gas that is to be supplied to the internal space IS. The second gas supply line 520 may supply the cleaning gas stored in the second gas storage unit 510 to the inside of the process chamber 100 by connecting the second gas storage unit 510 and the gas inlet port 110 to each other. The second valve 530 may be mounted on the second gas supply line 520 and may open and close the second gas supply line 520 or may adjust the flow rate of the cleaning gas supplied to the internal space IS.

In an embodiment, the cleaning gas may include a halogen-based gas for removing process by-products and the like formed in a deposition process. In an embodiment, the cleaning gas may include a fluorine-based gas for removing process by-products and the like formed in the deposition process. In an embodiment, the cleaning gas may include a chlorine-based gas for removing process by-products and the like formed in the deposition process. For example, the cleaning of the inside of the process chamber 100 may be performed by dry cleaning using a fluorine-based gas, but the present disclosure is not limited thereto. For example, the cleaning gas may include at least one of NF₃, SF₆, CF₄, CHF₃, CH₃F, CH₂F₂, C₂F₆, C₄F₈, HF, C₂F₄, C₃F₆, and C₄F₈. As used herein, the term “halogen” refers to a Group-17 element in the periodic table. In addition, the term “halogen” used herein may refer to a halogen element.

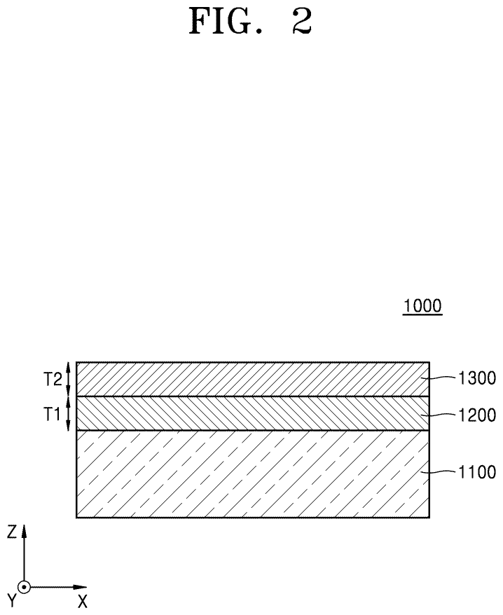

FIG. 2 is a cross-sectional view illustrating a component used in a semiconductor process, according to an embodiment. Descriptions are made with further reference to FIG. 1.

Referring to FIG. 2, a component 1000 may include a base material 1100, a first coating layer 1200, and a second coating layer 1300. Herein, the component 1000 may refer to a component constituting the process chamber 100.

The base material 1100, the first coating layer 1200, and the second coating layer 1300 may be sequentially stacked in the stated order. That is, the first coating layer 1200 may be stacked on the base material 1100, and the second coating layer 1300 may be stacked on the first coating layer 1200. In an embodiment, the first coating layer 1200 may be in contact with the base material 1100. The base material 1100 may be a layer that functions as the basis for the component 1000. The base material 1100 may include a ceramic and/or a metal. For example, the ceramic may include aluminum oxide, aluminum nitride, yttrium oxide, silicon carbide, silicon, silicon nitride, and/or zinc oxide. For example, the metal may include aluminum (Al), titanium (Ti), nickel (Ni), stainless steel (SUS), tungsten (W), and/or copper (Cu).

The first coating layer 1200 and the second coating layer 1300 may be formed on the base material 1100 and may protect the base material 1100. Therefore, the first coating layer 1200 and the second coating layer 1300 may improve the reliability of the component 1000. In an embodiment, each of the first coating layer 1200 and the second coating layer 1300 may be formed by an atomic layer deposition (ALD) method. In another embodiment, at least one of the first coating layer 1200 and the second coating layer 1300 may be formed by a chemical vapor deposition method, a sputtering method, and/or an electro-plating method.

Although FIG. 2 illustrates that a first coating layer 1200 as a single layer and the second coating layer 1300 as a single layer are stacked on the base material 1100, the present disclosure is not limited thereto. For example, a plurality of first coating layers 1200 and/or a plurality of second coating layers 1300 may be stacked on the base material 1100. For example, the first coating layers 1200 and the second coating layers 1300 may be alternately stacked on the base material 1100.

For example, the base material 1100 may include the process chamber 100 and/or the substrate support device 200 of FIG. 1. For example, the base material 1100 may include an inner wall of the process chamber 100, the shower head 130, the body 210, and/or the support 220 of FIG. 1. For example, the base material 1100 may include the heater of the body 210 of FIG. 1.

The first coating layer 1200 may be on the base material 1100 and may protect the base material 1100. In an embodiment, the first coating layer 1200 may cover one whole surface of the base material 1100. In an embodiment, the first coating layer 1200 may be in direct contact with the base material 1100. In another embodiment, the first coating layer 1200 may be spaced apart from the base material 1100. In an embodiment, the first coating layer 1200 may suppress radicals formed during a semiconductor process from permeating the base material 1100 and/or reacting with the base material 1100. In an embodiment, the first coating layer 1200 may suppress halogen radicals formed during a semiconductor process from permeating the base material 1100 and/or reacting with the base material 1100. For example, the first coating layer 1200 may suppress fluorine radicals formed during a semiconductor process from permeating the base material 1100 and/or reacting with the base material 1100. In an embodiment, the first coating layer 1200 may not include a porous layer. That is, the first coating layer 1200 may have a pore-free structure. In an embodiment, the first coating layer 1200 may not include pores and may include a dense structure. A first thickness T1, which is the thickness of the first coating layer 1200, may be about 0.1 nm to about 3000 nm.

The second coating layer 1300 may be on the first coating layer 1200. In an embodiment, the second coating layer 1300 may cover one whole surface of the first coating layer 1200. In an embodiment, the second coating layer 1300 may be configured to form a compound by reacting with radicals formed during a semiconductor process. In an embodiment, the second coating layer 1300 may be configured to form a halogen compound by reacting with halogen radicals formed during a semiconductor process. For example, the second coating layer 1300 may be configured to form a fluorine compound by reacting with fluorine radicals formed during a semiconductor process. A second thickness T2, which is the thickness of the second coating layer 1300, may be about 0.1 nm to about 3000 nm.

Each of the first coating layer 1200 and the second coating layer 1300 may include a metal oxide. Each of the first coating layer 1200 and the second coating layer 1300 may include, but is not limited to, yttrium (Y), plutonium (Pu), lanthanum (La), cerium (Ce), neodymium (Nd), uranium (U), gadolinium (Gd), erbium (Er), samarium (Sm), titanium (Ti), zirconium (Zr), aluminum (Al), and/or magnesium (Mg). The first coating layer 1200 and the second coating layer 1300 may respectively include different materials. Each of the first coating layer 1200 and the second coating layer 1300 may include a material according to a Formula shown below.

MₓO_{y} [Formula]

In the Formula, M may include, but is not limited to, yttrium (Y), plutonium (Pu), lanthanum (La), cerium (Ce), neodymium (Nd), uranium (U), gadolinium (Gd), erbium (Er), samarium (Sm), titanium (Ti), zirconium (Zr), aluminum (Al), and/or magnesium (Mg). O represents oxygen. x and y may each independently be a natural number of 1 to 15.

In an embodiment, when the first coating layer 1200 and the second coating layer 1300 are formed on the base material 1100 including a ceramic, the first coating layer 1200 and the second coating layer 1300 may each be configured to be resistant to peeling and/or cracking at a temperature of up to about 700° C. In an embodiment, when the first coating layer 1200 and the second coating layer 1300 are formed on the base material 1100 including a metal, the first coating layer 1200 and the second coating layer 1300 may each be configured to be resistant to peeling and/or cracking at a temperature of up to about 400° C. In addition, the first coating layer 1200 and the second coating layer 1300 may each suppress radicals from permeating the base material 1100 and/or reacting with the base material 1100 at a temperature of up to about 650° C.

In an embodiment, the metal constituting the first coating layer 1200 may be different from the metal constituting the second coating layer 1300. In another embodiment, the metal constituting the first coating layer 1200 may be the same as the metal constituting the second coating layer 1300.

The size of particles of the first coating layer 1200 may be different from the size of particles of the second coating layer 1300. In an embodiment, the size of the particles of the first coating layer 1200 may be less than the size of the particles of the second coating layer 1300. In another embodiment, the size of the particles of the first coating layer 1200 may be greater than the size of the particles of the second coating layer 1300. For example, the size of the particles of the first coating layer 1200 may be about 5 nm or less. For example, the size of the particles of the second coating layer 1300 may be about 6 nm to about 30 nm. When the size of each of the particles of the first coating layer 1200 is about 5 nm or less, the first coating layer 1200 may effectively suppress halogen radicals from permeating the base material 1100.

The second coating layer 1300 may be configured such that the vapor pressure of a compound of both the metal constituting the second coating layer 1300 and a halogen is lower than the vapor pressure of a compound of both the metal constituting the base material 1100 and/or the first coating layer 1200 and the halogen. When the second coating layer 1300 is configured such that the vapor pressure of a compound of both the metal constituting the second coating layer 1300 and a halogen constituting a radical generated by plasma formed in a semiconductor process is lower than the vapor pressure of a compound of both the metal constituting the base material 1100 and/or the first coating layer 1200 and the halogen, the sublimation of a halogen compound formed by a reaction between the halogen and the base material 1100 may be prevented, thereby preventing contamination in the process chamber 100, and the compound of both the metal of the second coating layer 1300 and the halogen may protect the first coating layer 1200.

For example, when the halogen includes fluorine, the second coating layer 1300 may be configured such that the vapor pressure of a compound of both the metal constituting the second coating layer 1300 and fluorine is lower than the vapor pressure of a compound of both the metal constituting the base material 1100 and/or the first coating layer 1200 and fluorine. For example, the second coating layer 1300 may be configured such that the vapor pressure of the compound of both the metal constituting the second coating layer 1300 and fluorine is lower than the vapor pressure of AlF₃. When the vapor pressure of the compound of both the metal constituting the second coating layer 1300 and the halogen is lower than the vapor pressure of the compound of both the metal constituting the base material 1100 and/or the first coating layer 1200 and the halogen, the sublimation of the second coating layer 1300 may be suppressed, thereby protecting the first coating layer 1200.

A process of depositing a thin film may include a process of removing by-products (for example, oxidized powder and the like) in a process chamber by using a halide gas. In this case, the halide gas may react with various components of a substrate processing apparatus, and in particular, a compound formed by a reaction between the halide gas and a certain component at high temperature may be sublimated and adsorbed onto a different component in the process chamber. Therefore, as a semiconductor process proceeds, because reflectivity, RF impedance, or the like in the process chamber may change, the reproducibility of the semiconductor process may be reduced, and the generation of defects in the semiconductor process may be increased.

Although the sublimation of the component may be suppressed by performing coating on the surface of the component and thus reducing the vapor pressure of the surface of the component, halogen radicals may permeate a base material to generate cracks in the base material in this case. Therefore, to prevent such issues, a technique capable of causing reaction by-products not to be sublimated at high temperature and suppressing halogen radicals from permeating a base material may be required.

For example, when the base material 1100 including a ceramic and/or a metal is used, a metal-halogen compound may be formed due to a cleaning gas including a halogen, during a cleaning process. For example, when the base material 1100 includes aluminum (Al) and the halogen includes fluorine, aluminum fluoride (AlF₃) may be formed due to the cleaning gas. The metal-halogen compound may be vaporized at high temperature and thus condensed and adsorbed on the inner wall of the process chamber 100 and/or the shower head 130, thereby changing the mechanical properties of the thin film or causing defects. In addition, because the metal-halogen compound formed at the grain boundary of the base material 1100 increases thermal stress acting on the base material 1100, cracks may be generated in the base material 1100.

On the other hand, because the substrate processing apparatus 10 of the present disclosure further includes the first coating layer 1200 protecting the base material 1100 and the second coating layer 1300 protecting the first coating layer 1200, the component 1000 of the substrate processing apparatus 10 may be protected. More specifically, because the first coating layer 1200 includes a dense layer having a small particle size, the first coating layer 1200 may suppress halogen radicals from permeating the base material 1100. In addition, because the second coating layer 1300 includes a material which allows a vapor pressure when the metal constituting the second coating layer 1300 is bonded to a halogen to be lower than a vapor pressure when the metal constituting the base material 1100 and/or the first coating layer 1200 is bonded to the halogen, the second coating layer 1300 may prevent the contamination of the process chamber 100 and may protect the first coating layer 1200 from halogen radicals. Therefore, the reliability of the component 1000 of the substrate processing apparatus 10 may improve, thereby reducing defects of a semiconductor device. In addition, the surface condition of the component 1000 of the substrate processing apparatus 10 may be maintained constant, thereby reducing changes over time in processes. For example, during a deposition process such as ALD, CVD, or physical vapor deposition (PVD), by suppressing a change in emissivity due to the formation of a metal-halogen compound on the shower head 130, the temperature of a substrate in a semiconductor fabrication process may be maintained constant, thereby maintaining the deposition rate of a film of a semiconductor device.

In addition, because the first coating layer 1200 and the second coating layer 1300 according to the present disclosure suppress bonding between the base material 1100 and halogen radicals, a cleaning process may be performed at relatively high temperature. Therefore, because the difference between a deposition process temperature and a cleaning process temperature may be reduced, turnaround time (TAT) may be reduced, thereby improving semiconductor process efficiency.

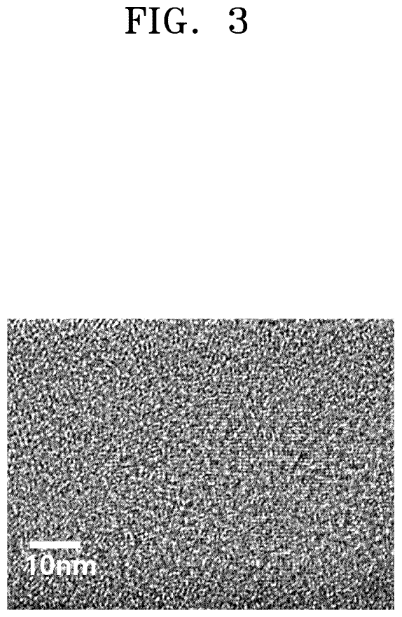

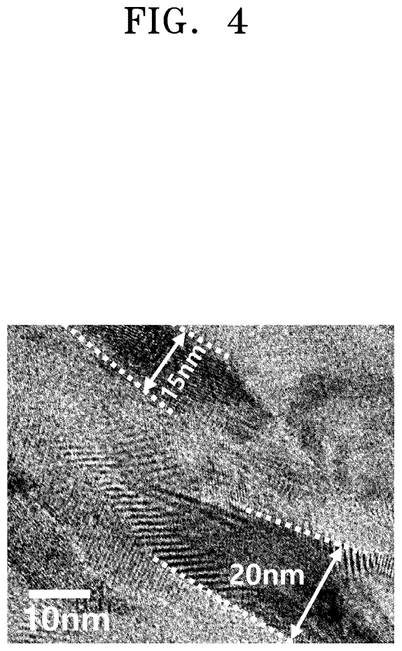

FIG. 3 is a transmission electron microscopy (TEM) image showing a first coating layer according to an embodiment, and FIG. 4 is a TEM image showing a second coating layer according to an embodiment. Descriptions are made with further reference to FIG. 2.

Referring to FIGS. 3 and 4, the size of particles constituting the first coating layer 1200 may be less than the size of particles constituting the second coating layer 1300. As described above, the particles constituting the first coating layer 1200 may be small enough for halogen radicals not to permeate the base material 1100. In addition, the first coating layer 1200 may include a relatively dense structure. The deviation in the size of the particles constituting the first coating layer 1200 may be less than the deviation in the size of the particles constituting the second coating layer 1300.

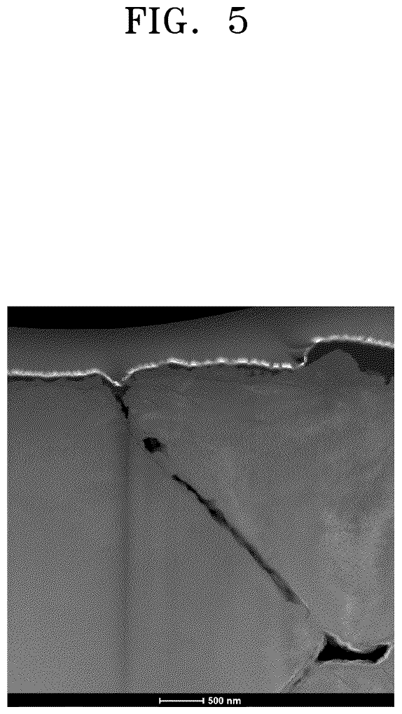

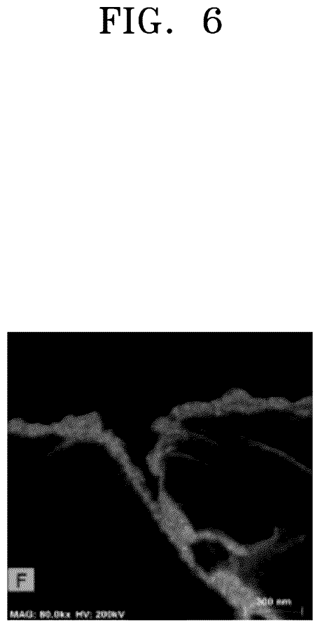

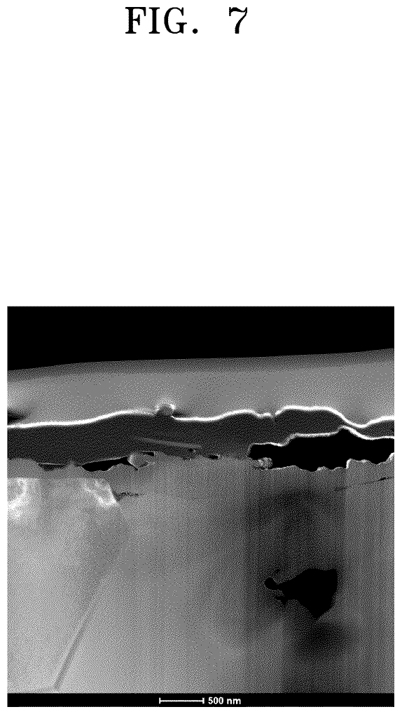

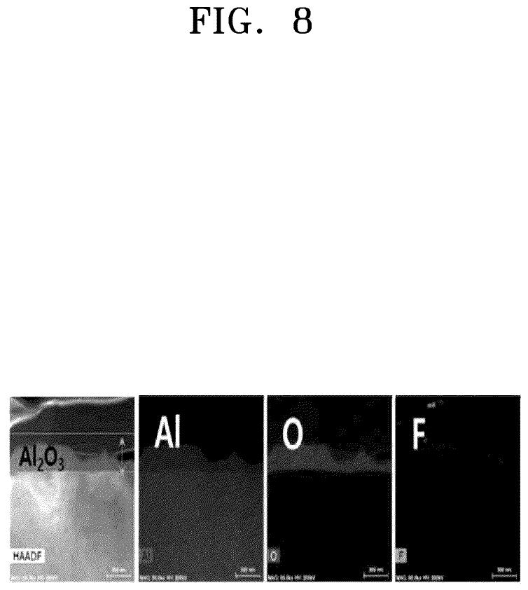

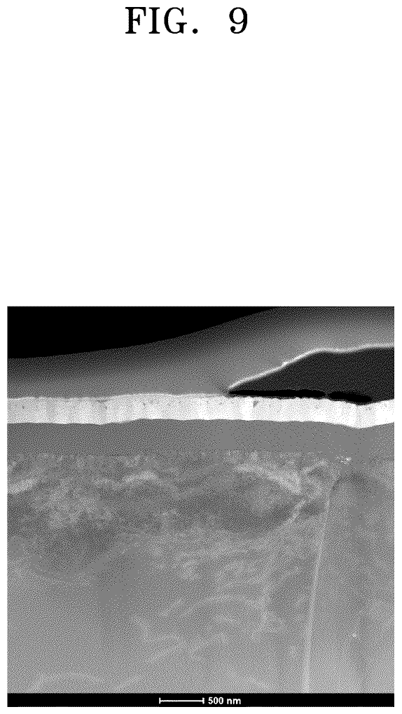

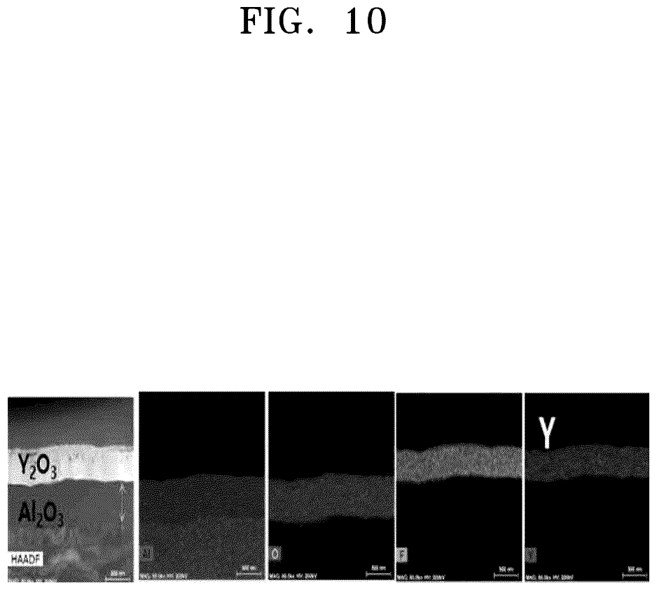

FIG. 5 is a TEM image showing a component after a cleaning process in Comparative Example 1, and FIG. 6 is an energy dispersive spectroscopy (EDS) mapping data image showing the component after the cleaning process in Comparative Example 1. FIG. 7 is a TEM image showing a component after a cleaning process in Comparative Example 2, and FIG. 8 is an EDS mapping data image showing the component after the cleaning process in Comparative Example 2. FIG. 9 is a TEM image showing a component after a cleaning process in an Example, and FIG. 10 is an EDS mapping data image showing the component after the cleaning process in the Example. Descriptions are made with further reference to FIG. 2.

FIGS. 5 and 6 illustrate an example in which the first coating layer 1200 and the second coating layer 1300 are not formed on the base material 1100, and FIGS. 7 and 8 illustrate an example in which the first coating layer 1200 as a single layer is formed on the base material 1100. FIGS. 9 and 10 illustrate an example in which the first coating layer 1200 and the second coating layer 1300 are formed on the base material 1100. More specifically, FIGS. 5 and 6 illustrate that where fluorine permeates the grain boundary of a ceramic base material 1100, cracks are generated in the base material 1100, and FIGS. 7 and 8 illustrate that where only the first coating layer 1200 including alumina is formed on the ceramic base material 1100, the surface of the first coating layer 1200 is etched. In addition, FIGS. 9 and 10 illustrate that where the first coating layer 1200 and the second coating layer 1300 are formed on the base material 1100, the first coating layer 1200 suppresses fluorine from permeating the base material 1100, and etching of the second coating layer 1300 in a high-temperature environment is suppressed.

Referring to FIGS. 5 to 10, when the component 1000 does not include a coating layer, as a metal-halogen compound is formed at the grain boundary of the base material 1100, as shown in FIGS. 5 and 6, cracks may be generated in the base material 1100 due to the difference in thermal stress. In addition, when the component 1000 includes only the first coating layer 1200, as a metal-halogen compound is vaporized, as shown in FIGS. 7 and 8, the process chamber 100 may be contaminated and it may be difficult to protect the surface of the base material 1100.

On the other hand, as the coating layers 1200 and 1300 on the base material 1100 of the Example of FIGS. 9 and 10 are not etched, and halogen radicals are not allowed to permeate up to the base material 1100, cracks may be suppressed from being generated in the base material 1100. FIG. 10 illustrates an example in which the second coating layer 1300 includes yttrium oxide, and from FIG. 10, it may be confirmed that fluorine (F) permeates only a layer including yttrium (Y) and is not allowed to permeate a region under the layer including yttrium (Y). Therefore, the base material 1100 may be protected from fluorine (F).

As described above, when a coating layer is not formed on the base material 1100, it may be difficult to suppress halogen radicals from permeating or reacting with the base material 1100. In addition, when only the first coating layer 1200 as a single layer is formed on the base material 1100, although the first coating layer 1200 may effectively suppress halogen radicals from physically permeating the base material 1100, the halogen radicals may react with the first coating layer 1200 and be sublimated to contaminate the process chamber 100.

Furthermore, although not shown, when only the second coating layer 1300 as a single layer is formed on the base material 1100, although the second coating layer 1300 does not contaminate the process chamber 100 through the vaporization thereof, halogen radicals may permeate the base material 1100 to form a metal-halogen compound at the grain boundary of the base material 1100, and thus, cracks may be generated in the base material 1100.

The component 1000 of the present disclosure may include the first coating layer 1200 and the second coating layer 1300, which are formed on the base material 1100. The first coating layer 1200 may effectively suppress halogen radicals from physically permeating the base material 1100, and the second coating layer 1300 may prevent the contamination of the process chamber 1000 and may protect the first coating layer 1200. Therefore, according to the substrate processing apparatus 10 of the present disclosure, the component 1000 may be effectively protected, and thus, a semiconductor process may be performed with high reliability.

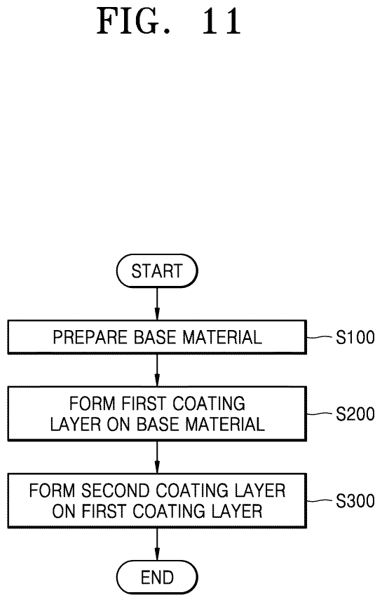

FIG. 11 is a flowchart illustrating a method of forming a plurality of coating layers on a base material, according to an embodiment. Descriptions are made with further reference to FIGS. 1 and 2.

Referring to FIG. 11, first, a base material 1100 may be prepared (S100). The base material 1100 may be a component of the substrate processing apparatus 10. As described above, the base material 1100 may include a ceramic and/or a metal. For example, the ceramic may include aluminum oxide, aluminum nitride, yttrium oxide, silicon carbide, silicon, silicon nitride, and/or zinc oxide. For example, the metal may include aluminum (Al), titanium (Ti), nickel (Ni), stainless steel (SUS), tungsten (W), and/or copper (Cu).

Next, a first coating layer 1200 may be formed on the base material 1100 (S200). In an embodiment, the first coating layer 1200 may be formed on the base material 1100 by an ALD method. In an embodiment, the first coating layer 1200 may be formed on the base material 1100 by a CVD method, a sputtering method, and/or an electro-plating method. However, a method of forming the first coating layer 1200 is not limited thereto, and the first coating layer 1200 may be formed by various methods.

As described above, the first coating layer 1200 may include a metal oxide. For example, the first coating layer 1200 may include yttrium (Y), plutonium (Pu), lanthanum (La), cerium (Ce), neodymium (Nd), uranium (U), gadolinium (Gd), erbium (Er), samarium (Sm), titanium (Ti), zirconium (Zr), aluminum (Al), and/or magnesium (Mg). A deposition process may be performed such that particles constituting the first coating layer 1200 have a size of about 5 nm or less. In an embodiment, when an ALD process is performed, the ALD process may include, but is not limited to, a reactant of CH₃COOH, HCOOH, H₂O, O₃, O₂, and/or O. In an embodiment, the ALD process may be performed at a temperature of about 50° C. to about 500° C.

To control the size of the particles of the first coating layer 1200, a method of controlling the number of cycles of a deposition process, performing additional surface treatment on the base material 1100, controlling the concentration or reaction conditions of a precursor, controlling a deposition process temperature, and/or performing post-heat treatment may be used.

In an embodiment, when the first coating layer 1200 is formed on the base material 1100 including a ceramic, the first coating layer 1200 may be configured to be resistant to peeling and/or cracking at a temperature of up to about 700° C. In an embodiment, when the first coating layer 1200 is formed on the base material 1100 including a metal, the first coating layer 1200 may be configured to be resistant to peeling and/or cracking at a temperature of up to about 400° C. In addition, the first coating layer 1200 may suppress radicals from permeating the base material 1100 and/or reacting with the base material 1100 at a temperature of up to about 650° C. The first coating layer 1200 may be formed with a thickness of about 0.1 nm to about 3000 nm.

Next, a second coating layer 1300 may be formed on the first coating layer 1200 (S300). In an embodiment, the second coating layer 1300 may be formed on the first coating layer 1200 by an ALD method. In another embodiment, the second coating layer 1300 may be formed on the first coating layer 1200 by a CVD method, a sputtering method, and/or an electro-plating method. However, a method of forming the second coating layer 1300 is not limited thereto, and the second coating layer 1300 may be formed by various methods.

As described above, the second coating layer 1300 may include a metal oxide. For example, the second coating layer 1300 may include yttrium (Y), plutonium (Pu), lanthanum (La), cerium (Ce), neodymium (Nd), uranium (U), gadolinium (Gd), erbium (Er), samarium (Sm), titanium (Ti), zirconium (Zr), aluminum (Al), and/or magnesium (Mg). An ALD process may be performed such that particles constituting the second coating layer 1300 have a size of about 6 nm to about 30 nm. In an embodiment, when the ALD process is performed, the ALD process may include, but is not limited to, a reactant of CH₃COOH, HCOOH, H₂O, O₃, O₂, and/or O. In an embodiment, the ALD process may be performed at a temperature of about 50° C. to about 500° C.

The second coating layer 1300 may be configured such that the vapor pressure of a compound of both a metal constituting the second coating layer 1300 and a halogen constituting radicals generated by plasma formed in a process is lower than the vapor pressure of a compound of both a metal constituting the base material 1100 and/or the first coating layer 1200 and the halogen. For example, when the halogen includes fluorine, the second coating layer 1300 may be configured such that the vapor pressure of a compound of both the metal constituting the second coating layer 1300 and fluorine is lower than the vapor pressure of a compound of both the metal constituting the base material 1100 and/or the first coating layer 1200 and fluorine. For example, the second coating layer 1300 may be configured such that the vapor pressure of the compound of both the metal constituting the second coating layer 1300 and fluorine is lower than the vapor pressure of AlF₃. When the vapor pressure of a compound of both the metal constituting the second coating layer 1300 and the halogen is lower than the vapor pressure of the compound of both the metal constituting the base material 1100 and/or the first coating layer 1200 and the halogen, the sublimation of the second coating layer 1300 is suppressed, so the first coating layer 1200 may be protected.

In an embodiment, when the second coating layer 1300 is formed over the base material 1100 including a ceramic, the second coating layer 1300 may be configured to be resistant to peeling and/or cracking at a temperature of up to about 700° C. In an embodiment, when the second coating layer 1300 is formed over the base material 1100 including a metal, the second coating layer 1300 may be configured to be resistant to peeling and/or cracking at a temperature of up to about 400° C. In addition, the second coating layer 1300 may suppress radicals from permeating the base material 1100 and/or reacting with the base material 1100 at a temperature of up to about 650° C. The second coating layer 1300 may be formed with a thickness of about 0.1 nm to about 3000 nm.

Heretofore, the method of forming the first coating layer 1200 and the second coating layer 1300 on the base material 1100 has been described. The first coating layer 1200 and the second coating layer 1300 may be formed before the base material 1100 is mounted in the process chamber 100.

While the present disclosure has been particularly shown and described with reference to embodiments thereof, it will be understood that various changes in form and details may be made therein without departing from the spirit and scope of the following claims.

What is claimed is:

1. A component used in a semiconductor process, the component comprising:
a base material that comprises at least one of a metal and a ceramic;
a first coating layer on the base material and configured to suppress halogen radicals from physically permeating the base material; and
a second coating layer on the first coating layer,
wherein the first coating layer comprises particles having a size sufficient to suppress the halogen radicals from permeating the base material.

2. The component of claim 1, wherein the first coating layer comprises a metal oxide.

3. The component of claim 1, wherein the first coating layer comprises at least one of yttrium (Y), plutonium (Pu), lanthanum (La), cerium (Ce), neodymium (Nd), uranium (U), gadolinium (Gd), erbium (Er), samarium (Sm), titanium (Ti), zirconium (Zr), aluminum (Al), and magnesium (Mg).

4. The component of claim 1, wherein particles constituting the first coating layer have a size of about 5 nm or less.

5. The component of claim 1, wherein the first coating layer has a pore-free structure.

6. The component of claim 1, wherein, when the base material comprises a metal, the first coating layer is configured to be resistant to peeling and cracking at a temperature of up to about 400° C.

7. The component of claim 1, wherein, when the base material comprises a ceramic, the first coating layer is configured to be resistant to peeling and cracking by halogen radicals at a temperature of up to about 700° C.

8. The component of claim 1, wherein the first coating layer has a thickness of about 0.1 nm to about 3000 nm.

9. A component used in a semiconductor process, the component comprising:
a base material that comprises at least one of a metal and ceramic;
a first coating layer on the base material; and
a second coating layer on the first coating layer and configured to protect the first coating layer,
wherein a vapor pressure of a compound of both a metal constituting the second coating layer and a halogen is less than a vapor pressure of a compound of both a metal constituting at least one of the base material and the first coating layer and the halogen.

10. The component of claim 9, wherein the second coating layer is represented by a Formula shown below:
MₓO_{y} [Formula]
wherein, in the Formula, M comprises at least one of yttrium (Y), plutonium (Pu), lanthanum (La), cerium (Ce), neodymium (Nd), uranium (U), gadolinium (Gd), erbium (Er), samarium (Sm), titanium (Ti), zirconium (Zr), aluminum (Al), and magnesium (Mg), and x and y are each independently a natural number of 1 to 15.

11. The component of claim 9, wherein particles constituting the second coating layer have a size of about 6 nm to about 30 nm.

12. The component of claim 9, wherein, when the base material comprises a metal, the second coating layer is configured to be resistant to peeling and cracking at a temperature of up to about 400° C.

13. The component of claim 9, wherein, when the base material comprises a ceramic, the second coating layer is configured to be resistant to peeling and cracking at a temperature of up to about 700° C.

14. The component of claim 9, wherein the second coating layer is configured to suppress halogen radicals from reacting with the base material at a temperature of up to about 650° C.

15. The component of claim 9, wherein the second coating layer has a thickness of about 0.1 nm to about 3000 nm.

16. The component of claim 9, wherein a vapor pressure of a compound of both a metal constituting the second coating layer and fluorine is less than a vapor pressure of aluminum fluoride.

17. A semiconductor process chamber used in a semiconductor process, the semiconductor process chamber comprising a component that comprises at least one of a metal and a ceramic,
wherein the component comprises:
a base material comprising at least one of a metal and a ceramic;
a first coating layer on the base material and configured to suppress halogen radicals from physically permeating the base material; and
a second coating layer on the first coating layer and configured to protect the first coating layer,
the first coating layer comprises particles having a size sufficient to suppress the halogen radicals from permeating the base material, and
a vapor pressure of a compound of both a metal constituting the second coating layer and a halogen is less than a vapor pressure of a compound of both a metal constituting at least one of the base material and the first coating layer and the halogen.

18. The semiconductor process chamber of claim 17, wherein the size of the particles constituting the first coating layer is less than a size of particles constituting the second coating layer.

19. The semiconductor process chamber of claim 17, wherein a vapor pressure of a compound of both the metal constituting the second coating layer and fluorine is less than a vapor pressure of aluminum fluoride.

20. The semiconductor process chamber of claim 17, wherein the component comprises at least one of a substrate supporting device, a process chamber, and a shower head.
